(19) United States
(12) Patent Application Publication
(10) Pub. No.: US 2009/0151992 A1
(43) Pub. Date: Jun. 18, 2009

(54) FORMATION AND INTEGRATION OF PASSIVE STRUCTURES USING SILICON AND PACKAGE SUBSTRATE

(75) Inventor: ALI SARFARAZ, Alamo, CA (US)

Correspondence Address: GARLICK HARRISON & MARKISON, P.O. BOX 160727, AUSTIN, TX, 78716-0727, US

(73) Assignee: BROADCOM CORPORATION, Irvine, CA (US)

(21) Appl. No.: 11/959,290

(22) Filed: Dec. 18, 2007

(51) Int. Cl. H05K 1/11

(52) U.S. Cl. 174/261

(57) ABSTRACT

An integrated circuit radio transceiver and method therefor includes an integrated circuit package that comprises a first substrate device, first and second nodes of a circuit on an outer surface of the first substrate device, a second substrate device and a trace on the second substrate device to provide crossover coupling. First and second bumps coupling the trace on the second substrate device to the first and second nodes on the first substrate device operable to provide crossover coupling.

### BACKGROUND

1. Technical Field

The present invention relates to wireless communications and, more particularly, to circuitry for integrated circuits for wireless communications and other applications.

2. Related Art

Communication systems are known to support wireless and wire lined communications between wireless and/or wire lined communication devices. Such communication systems range from national and/or international cellular telephone systems to the Internet to point-to-point in-home wireless networks. Each type of communication system is constructed, and hence operates, in accordance with one or more communication standards. For instance, wireless communication systems may operate in accordance with one or more standards, including, but not limited to, IEEE 802.11, Bluetooth, advanced mobile phone services (AMPS), digital AMPS, global system for mobile communications (GSM), code division multiple access (CDMA), local multi-point distribution systems (LMDS), multi-channel-multi-point distribution systems (MMDS), and/or variations thereof.

Depending on the type of wireless communication system, a wireless communication device, such as a cellular telephone, two-way radio, personal digital assistant (PDA), personal computer (PC), laptop computer, home entertainment equipment, etc., communicates directly or indirectly with other wireless communication devices. For direct communications (also known as point-to-point communications), the participating wireless communication devices tune their receivers and transmitters to the same channel or channels (e.g., one of a plurality of radio frequency (RF) carriers of the wireless communication system) and communicate over that channel(s). For indirect wireless communications, each wireless communication device communicates directly with an associated base station (e.g., for cellular services) and/or an associated access point (e.g., for an in-home or in-building wireless network) via an assigned channel. To complete a communication connection between the wireless communication devices, the associated base stations and/or associated access points communicate with each other directly, via a system controller, via a public switch telephone network (PSTN), via the Internet, and/or via some other wide area network.

Each wireless communication device includes a built-in radio transceiver (i.e., receiver and transmitter) or is coupled to an associated radio transceiver (e.g., a station for in-home and/or in-building wireless communication networks, RF modem, etc.). As is known, the transmitter includes a data modulation stage, one or more intermediate frequency stages, and a power amplifier stage. The data modulation stage converts raw data into baseband signals in accordance with the particular wireless communication standard. The one or more intermediate frequency stages mix the baseband signals with one or more local oscillations to produce RF signals. The power amplifier stage amplifies the RF signals prior to transmission via an antenna.

Typically, the data modulation stage is implemented on a baseband processor chip, while the intermediate frequency (IF) stages and power amplifier stage are implemented on a separate radio processor chip. Historically, radio integrated circuits have been designed using bi-polar circuitry, allowing for large signal swings and linear transmitter component behavior. Therefore, many legacy baseband processors employ analog interfaces that communicate analog signals to and from the radio processor.

FIG. 1 is a diagram that illustrates a prior art structure and method for a crossover connection on an integrated circuit die or on a substrate material. As may be seen, a substrate material 003 includes conductive traces 005 on both sides of substrate material 003. Traces 005 are each connected to a via shown generally at 007 by lead lines 009. Via 007 penetrates substrate material 003 and operably provides a circuit path from one side of substrate material 003 to the other side. As such, crossover connections may be established using traces on an opposite surface of a substrate material (either a bare die or other substrate material). Such a typical approach, however, requires use of vias such as via 007 which are very large in relation to today sub-micron scaling for devices.

### SUMMARY OF THE INVENTION

The present invention is directed to apparatus and methods of operation that are further described in the following Brief Description of the Drawings, the Detailed Description of the Invention, and the claims. Other features and advantages of the present invention will become apparent from the following detailed description of the invention made with reference to the accompanying drawings.

### BRIEF DESCRIPTION OF THE DRAWINGS

A better understanding of the present invention can be obtained when the following detailed description of the preferred embodiment is considered with the following drawings, in which:

FIG. 1 is a diagram that illustrates a prior art structure and method for a crossover connection on an integrated circuit die or on a substrate material;

FIG. 2 is a network diagram illustrating integrated circuit transceiver circuitry that employ the embodiments of the present invention;

FIGS. 3 and 4 are schematic block diagrams illustrating wireless communication devices that include a host device and an associated radio according to two different embodiments of the invention;

FIG. 5 is a functional diagram illustrating a structure and method according to one embodiment of the invention;

FIG. 6 is a functional diagram illustrating a structure and method according to one embodiment of the invention in which traces on at least three surfaces are operably coupled utilizing, in part, circuitry and methods of the embodiments of the present invention;

FIG. 7 is a functional schematic diagram of a coil utilizing the structure and method according to one embodiment of the invention;

FIG. 8 is a functional diagram that illustrates yet another aspect of the embodiments of the invention; and

FIG. 9 is a flow chart illustrating a method according to one embodiment of the present invention.

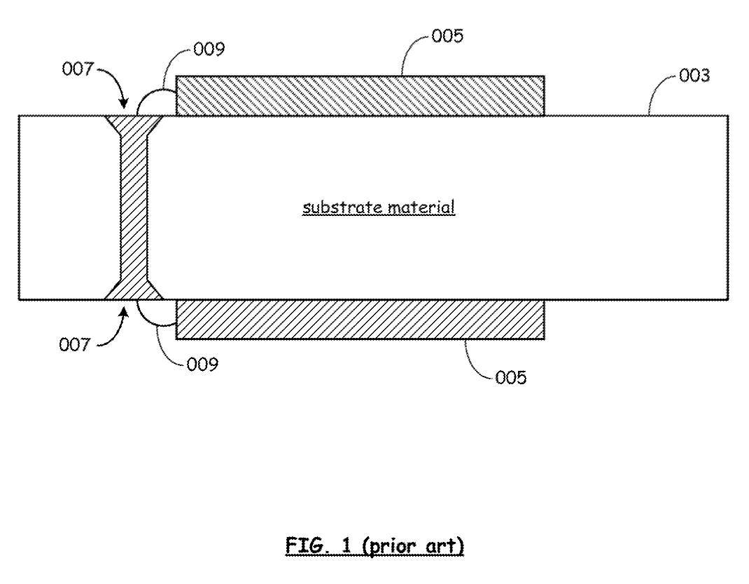

### DETAILED DESCRIPTION OF THE DRAWINGS

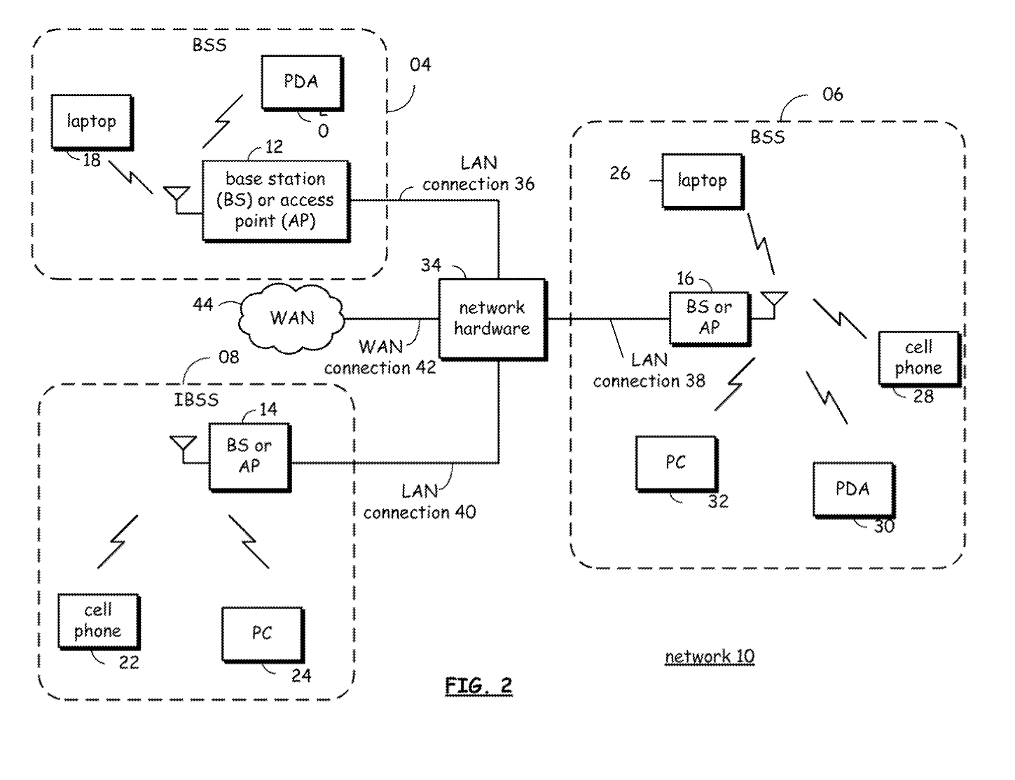

FIG. 2 is a functional block diagram illustrating a communication system that includes circuit devices and network elements and operation thereof according to one embodiment of the invention. More specifically, a plurality of network service areas 04, 06 and 08 are a part of a network 10. Network 10 includes a plurality of base stations or access points (APs) 12-16, a plurality of wireless communication devices 18-32 and a network hardware component 34. The wireless communication devices 18-32 may be laptop computers 18 and 26, personal digital assistants 20 and 30, personal computers 24 and 32 and/or cellular telephones 22 and 28. The details of the wireless communication devices will be described in greater detail with reference to FIGS. 2-10.

The base stations or APs 12-16 are operably coupled to the network hardware component 34 via local area network (LAN) connections 36, 38 and 40. The network hardware component 34, which may be a router, switch, bridge, modem, system controller, etc., provides a wide area network (WAN) connection 42 for the communication system 10 to an external network element such as WAN 44. Each of the base stations or access points 12-16 has an associated antenna or antenna array to communicate with the wireless communication devices in its area. Typically, the wireless communication devices 18-32 register with the particular base station or access points 12-16 to receive services from the communication system 10. For direct connections (i.e., point-to-point communications), wireless communication devices communicate directly via an allocated channel.

Typically, base stations are used for cellular telephone systems and like-type systems, while access points are used for in-home or in-building wireless networks. Regardless of the particular type of communication system, each wireless communication device includes a built-in radio and/or is coupled to a radio.

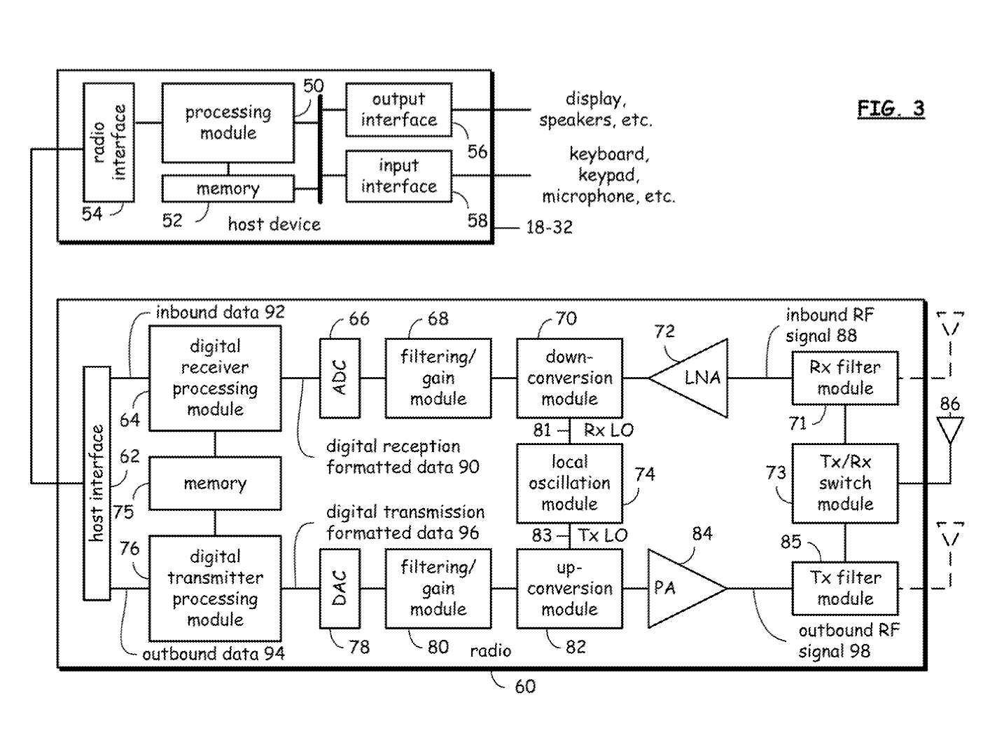

FIG. 3 is a schematic block diagram illustrating a wireless communication host device 18-32 and an associated radio 60. For cellular telephone hosts, radio 60 is a built-in component. For personal digital assistants hosts, laptop hosts, and/or personal computer hosts, the radio 60 may be built-in or an externally coupled component.

As illustrated, wireless communication host device 18-32 includes a processing module 50, a memory 52, a radio interface 54, an input interface 58 and an output interface 56. Processing module 50 and memory 52 execute the corresponding instructions that are typically done by the host device. For example, for a cellular telephone host device, processing module 50 performs the corresponding communication functions in accordance with a particular cellular telephone standard.

Radio interface 54 allows data to be received from and sent to radio 60. For data received from radio 60 (e.g., inbound data), radio interface 54 provides the data to processing module 50 for further processing and/or routing to output interface 56. Output interface 56 provides connectivity to an output device such as a display, monitor, speakers, etc., such that the received data may be displayed. Radio interface 54 also provides data from processing module 50 to radio 60. Processing module 50 may receive the outbound data from an input device such as a keyboard, keypad, microphone, etc., via input interface 58 or generate the data itself. For data received via input interface 58, processing module 50 may perform a corresponding host function on the data and/or route it to radio 60 via radio interface 54.

Radio 60 includes a host interface 62, a digital receiver processing module 64, an analog-to-digital converter 66, a filtering/gain module 68, a down-conversion module 70, a low noise amplifier 72, a receiver filter module 71, a transmitter/receiver (Tx/Rx) switch module 73, a local oscillation module 74, a memory 75, a digital transmitter processing module 76, a digital-to-analog converter 78, a filtering/gain module 80, an up-conversion module 82, a power amplifier 84, a transmitter filter module 85, and an antenna 86 operatively coupled as shown. The antenna 86 is shared by the transmit and receive paths as regulated by the Tx/Rx switch module 73. The antenna implementation will depend on the particular standard to which the wireless communication device is compliant.

Digital receiver processing module 64 and digital transmitter processing module 76, in combination with operational instructions stored in memory 75, execute digital receiver functions and digital transmitter functions, respectively. The digital receiver functions include, but are not limited to, demodulation, constellation demapping, decoding, and/or descrambling. The digital transmitter functions include, but are not limited to, scrambling, encoding, constellation mapping, and modulation. Digital receiver and transmitter processing modules 64 and 76, respectively, may be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions.

Memory 75 may be a single memory device or a plurality of memory devices. Such a memory device may be a read-only memory, random access memory, volatile memory, non-volatile memory, static memory, dynamic memory, flash memory, and/or any device that stores digital information. Note that when digital receiver processing module 64 and/or digital transmitter processing module 76 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry. Memory 75 stores, and digital receiver processing module 64 and/or digital transmitter processing module 76 executes, operational instructions corresponding to at least some of the functions illustrated herein.

In operation, radio 60 receives outbound data 94 from wireless communication host device 18-32 via host interface 62. Host interface 62 routes outbound data 94 to digital transmitter processing module 76, which processes outbound data 94 in accordance with a particular wireless communication standard or protocol (e.g., IEEE 802.11(a), IEEE 802.11b, Bluetooth, etc.) to produce digital transmission formatted data 96. Digital transmission formatted data 96 will be a digital baseband signal or a digital low IF signal, where the low IF typically will be in the frequency range of one hundred kilohertz to a few megahertz.

Digital-to-analog converter 78 converts digital transmission formatted data 96 from the digital domain to the analog domain. Filtering/gain module 80 filters and/or adjusts the gain of the analog baseband signal prior to providing it to up-conversion module 82. Up-conversion module 82 directly converts the analog baseband signal, or low IF signal, into an RF signal based on a transmitter local oscillation 83 provided by local oscillation module 74. Power amplifier 84 amplifies the RF signal to produce an outbound RF signal 98, which is filtered by transmitter filter module 85. The antenna 86 transmits outbound RF signal 98 to a targeted device such as a base station, an access point and/or another wireless communication device.

Radio 60 also receives an inbound RF signal 88 via antenna 86, which was transmitted by a base station, an access point, or another wireless communication device. The antenna 86 provides inbound RF signal 88 to receiver filter module 71 via Tx/Rx switch module 73, where Rx filter module 71 bandpass filters inbound RF signal 88. The Rx filter module 71 provides the filtered RF signal to low noise amplifier 72, which amplifies inbound RF signal 88 to produce an amplified inbound RF signal. Low noise amplifier 72 provides the amplified inbound RF signal to down-conversion module 70, which directly converts the amplified inbound RF signal into an inbound low IF signal or baseband signal based on a receiver local oscillation 81 provided by local oscillation module 74. Down-conversion module 70 provides the inbound low IF signal or baseband signal to filtering/gain module 68. Filtering/gain module 68 may be implemented in accordance with the teachings of the present invention to filter and/or attenuate the inbound low IF signal or the inbound baseband signal to produce a filtered inbound signal.

Analog-to-digital converter 66 converts the filtered inbound signal from the analog domain to the digital domain to produce digital reception formatted data 90. Digital receiver processing module 64 decodes, descrambles, demaps, and/or demodulates digital reception formatted data 90 to recapture inbound data 92 in accordance with the particular wireless communication standard being implemented by radio 60. Host interface 62 provides the recaptured inbound data 92 to the wireless communication host device 18-32 via radio interface 54.

As one of average skill in the art will appreciate, the wireless communication device of FIG. 3 may be implemented using one or more integrated circuits. For example, the host device may be implemented on a first integrated circuit, while digital receiver processing module 64, digital transmitter processing module 76 and memory 75 may be implemented on a second integrated circuit, and the remaining components of radio 60, less antenna 86, may be implemented on a third integrated circuit. As an alternate example, radio 60 may be implemented on a single integrated circuit. As yet another example, processing module 50 of the host device and digital receiver processing module 64 and digital transmitter processing module 76 may be a common processing device implemented on a single integrated circuit.

Memory 52 and memory 75 may be implemented on a single integrated circuit and/or on the same integrated circuit as the common processing modules of processing module 50, digital receiver processing module 64, and digital transmitter processing module 76. As will be described, it is important that accurate oscillation signals are provided to mixers and conversion modules. A source of oscillation error is noise coupled into oscillation circuitry through integrated circuitry biasing circuitry. One embodiment of the present invention reduces the noise by providing a selectable pole low pass filter in current mirror devices formed within the one or more integrated circuits.

Local oscillation module 74 includes circuitry for adjusting an output frequency of a local oscillation signal provided therefrom. Local oscillation module 74 receives a frequency correction input that it uses to adjust an output local oscillation signal to produce a frequency corrected local oscillation signal output. While local oscillation module 74, up-conversion module 82 and down-conversion module 70 are implemented to perform direct conversion between baseband and RF, it is understood that the principles herein may also be applied readily to systems that implement an intermediate frequency conversion step at a low intermediate frequency.

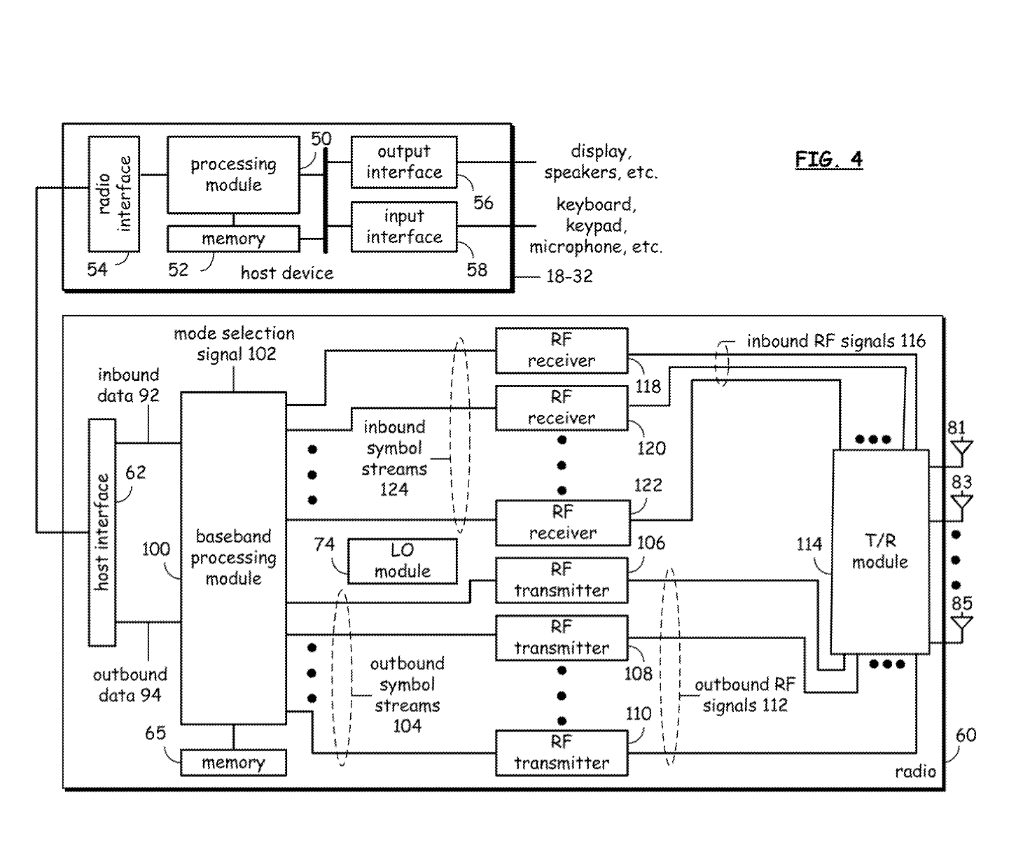

FIG. 4 is a schematic block diagram illustrating a wireless communication device that includes the host device 18-32 and an associated radio 60. For cellular telephone hosts, the radio 60 is a built-in component. For personal digital assistants hosts, laptop hosts, and/or personal computer hosts, the radio 60 may be built-in or an externally coupled component.

As illustrated, the host device 18-32 includes a processing module 50, memory 52, radio interface 54, input interface 58 and output interface 56. The processing module 50 and memory 52 execute the corresponding instructions that are typically done by the host device. For example, for a cellular telephone host device, the processing module 50 performs the corresponding communication functions in accordance with a particular cellular telephone standard.

The radio interface 54 allows data to be received from and sent to the radio 60. For data received from the radio 60 (e.g., inbound data), the radio interface 54 provides the data to the processing module 50 for further processing and/or routing to the output interface 56. The output interface 56 provides connectivity to an output display device such as a display, monitor, speakers, etc., such that the received data may be displayed. The radio interface 54 also provides data from the processing module 50 to the radio 60. The processing module 50 may receive the outbound data from an input device such as a keyboard, keypad, microphone, etc., via the input interface 58 or generate the data itself For data received via the input interface 58, the processing module 50 may perform a corresponding host function on the data and/or route it to the radio 60 via the radio interface 54.

Radio 60 includes a host interface 62, a baseband processing module 100, memory 65, a plurality of radio frequency (RF) transmitters 106-110, a transmit/receive (T/R) module 114, a plurality of antennas 81-85, a plurality of RF receivers 118-120, and a local oscillation module 74. The baseband processing module 100, in combination with operational instructions stored in memory 65, executes digital receiver functions and digital transmitter functions, respectively. The digital receiver functions include, but are not limited to, digital intermediate frequency to baseband conversion, demodulation, constellation demapping, decoding, de-interleaving, fast Fourier transform, cyclic prefix removal, space and time decoding, and/or descrambling. The digital transmitter functions include, but are not limited to, scrambling, encoding, interleaving, constellation mapping, modulation, inverse fast Fourier transform, cyclic prefix addition, space and time encoding, and digital baseband to IF conversion. The baseband processing module 100 may be implemented using one or more processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 65 may be a single memory device or a plurality of memory devices. Such a memory device may be a read-only memory, random access memory, volatile memory, non-volatile memory, static memory, dynamic memory, flash memory, and/or any device that stores digital information. Note that when the baseband processing module 100 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry.

In operation, the radio 60 receives outbound data 94 from the host device via the host interface 62. The baseband processing module 100 receives the outbound data 94 and, based on a mode selection signal 102, produces one or more outbound symbol streams 104. The mode selection signal 102 will indicate a particular mode of operation that is compliant with one or more specific modes of the various IEEE 802.11 standards. For example, the mode selection signal 102 may indicate a frequency band of 2.4 GHz, a channel bandwidth of 20 or 22 MHz and a maximum bit rate of 54 megabits-per-second. In this general category, the mode selection signal will further indicate a particular rate ranging from 1 megabit-per-second to 54 megabits-per-second. In addition, the mode selection signal will indicate a particular type of modulation, which includes, but is not limited to, Barker Code Modulation, BPSK, QPSK, CCK, 16 QAM and/or 64 QAM. The mode selection signal 102 may also include a code rate, a number of coded bits per subcarrier (NBPSC), coded bits per OFDM symbol (NCBPS), and/or data bits per OFDM symbol (NDBPS). The mode selection signal 102 may also indicate a particular channelization for the corresponding mode that provides a channel number and corresponding center frequency. The mode selection signal 102 may further indicate a power spectral density mask value and a number of antennas to be initially used for a MIMO communication.

The baseband processing module 100, based on the mode selection signal 102 produces one or more outbound symbol streams 104 from the outbound data 94. For example, if the mode selection signal 102 indicates that a single transmit antenna is being utilized for the particular mode that has been selected, the baseband processing module 100 will produce a single outbound symbol stream 104. Alternatively, if the mode selection signal 102 indicates 2, 3 or 4 antennas, the baseband processing module 100 will produce 2, 3 or 4 outbound symbol streams 104 from the outbound data 94.

Depending on the number of outbound symbol streams 104 produced by the baseband processing module 100, a corresponding number of the RF transmitters 106-110 will be enabled to convert the outbound symbol streams 104 into outbound RF signals 112. In general, each of the RF transmitters 106-110 includes a digital filter and upsampling module, a digital-to-analog conversion module, an analog filter module, a frequency up conversion module, a power amplifier, and a radio frequency bandpass filter. The RF transmitters 106-110 provide the outbound RF signals 112 to the transmit/receive module 114, which provides each outbound RF signal to a corresponding antenna 81-85.

When the radio 60 is in the receive mode, the transmit/receive module 114 receives one or more inbound RF signals 116 via the antennas 81-85 and provides them to one or more RF receivers 118-122. The RF receiver 118-122 converts the inbound RF signals 116 into a corresponding number of inbound symbol streams 124. The number of inbound symbol streams 124 will correspond to the particular mode in which the data was received. The baseband processing module 100 converts the inbound symbol streams 124 into inbound data 92, which is provided to the host device 18-32 via the host interface 62.

As one of average skill in the art will appreciate, the wireless communication device of FIG. 4 may be implemented using one or more integrated circuits. For example, the host device may be implemented on a first integrated circuit, the baseband processing module 100 and memory 65 may be implemented on a second integrated circuit, and the remaining components of the radio 60, less the antennas 81-85, may be implemented on a third integrated circuit. As an alternate example, the radio 60 may be implemented on a single integrated circuit. As yet another example, the processing module 50 of the host device and the baseband processing module 100 may be a common processing device implemented on a single integrated circuit. Further, the memory 52 and memory 65 may be implemented on a single integrated circuit and/or on the same integrated circuit as the common processing modules of processing module 50 and the baseband processing module 100.

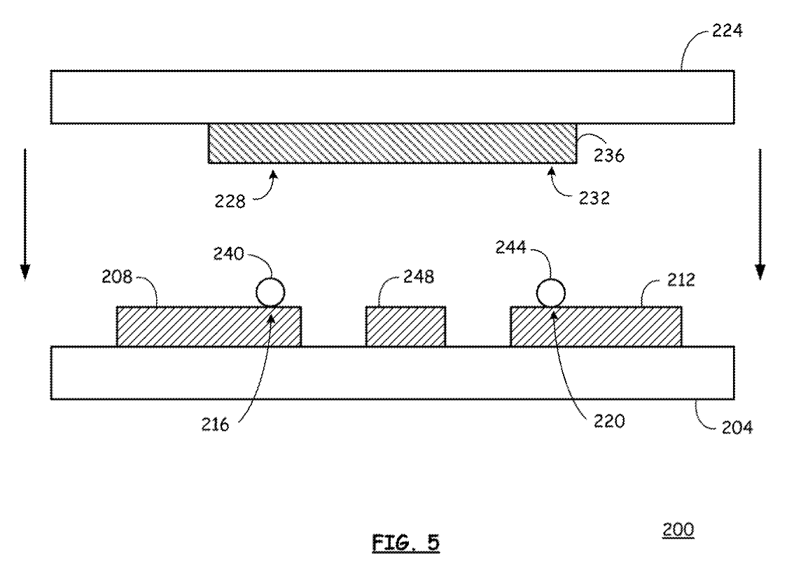

FIG. 5 is a functional diagram illustrating a structure and method according to one embodiment of the invention. More specifically, FIG. 5 may represent, for example, an integrated circuit package 200 that includes a first substrate 204 that further includes a first circuit path that requires a crossover connection. The first circuit path thus comprises a first trace 208 and a second trace 212 on an outer surface of the first substrate 204 operably coupling first and second electrical connection points shown generally at 216 and 220 on the first substrate 204. As may further be seen, a second substrate 224 includes a second circuit path that further comprises third and fourth electrical connection points 228 and 232 on the second substrate device 224.

More specifically, the second path on the second substrate device 224 includes a third trace 236 formed on the second substrate device 224. The package 200 further includes first and second bumps 240 and 244, respectively, coupling third and fourth electrical points 228 and 232 of the third trace 236 on the second substrate device 224 to the first and second electrical points 216 and 220 of the first and second traces 208 and 212 on the first substrate device 204 to form a hybrid passive structure to provide crossover coupling. In the illustrated embodiment, the first and second circuit paths are operably coupled through bumps 240 and 244 to define a crossover circuit path that crosses over a circuit trace such as trace 248. As is suggested by FIG. 5, the second substrate is placed to be aligned and in contact with bumps 240 and 244 to create a signal path from trace 208 through bump 240 to trace 236 and then through bump 244 to trace 212 without electrically contacting trace 248.

The integrated circuit package operably support transmission of a signal over a plurality of signal traces that cross each other without requiring a via to form a cross over connection of signal paths conducted on traces on an outer surface of a substrate (die or, for example, a printed circuit board). The bumps, for example, the first and second bumps of FIG. 5, are both substantially smaller than a typical via used to create alternate signal paths with a substrate device to support crossover signal paths.

In one example, a typical via aperture for receiving a metal fill may be 500 micrometers in diameter. A surrounding via pad may add another 350 micrometers of diameter while a typical clearance may add yet another 200 micrometers. Thus, a typical via may require about 1 millimeter diameter of IC real estate. In contrast, bumps such as the first and second bumps may be formed to define a 75 micrometer diameter and further only requiring an additional 75 micrometer clearance. In total, therefore, a space required for a bump may be ⅙^{th} or less in size than what is required for a via. In the described embodiment, a standard copper bump is utilized although any known technology for making bumps may be utilized.

In one embodiment of the invention, the first and second substrate devices may be any one of a number of different structures. For example, in one embodiment, the first substrate device comprises a flip chip and the second substrate device comprises one of a printed circuit board or a package substrate. Alternatively, the first substrate device may comprise one of a printed circuit board or a package substrate and the second substrate device comprises a flip chip. In yet another embodiment, the first substrate device may comprise a first die of a multi-chip module and the second substrate device may comprise a second die of a multi-chip module.

The applications for the described embodiments of the invention also include board to package substrate, package substrate to a silicon device, board to package to silicon device, and board to package for direct chip attachment configurations. Moreover, the embodiments may be utilized in conjunction with silicon device to package substrate configurations. In general, the embodiments of the invention comprise using a surface of an adjacent substrate or structure and bumps to contact a trace or strip thereon to provide crossover connections to avoid or reduce a number of vias that are used in a die or other substrate. The term “substrate” as used herein therefore may be used in conjunction with each of the above cited structures and other similar and equivalent structures.

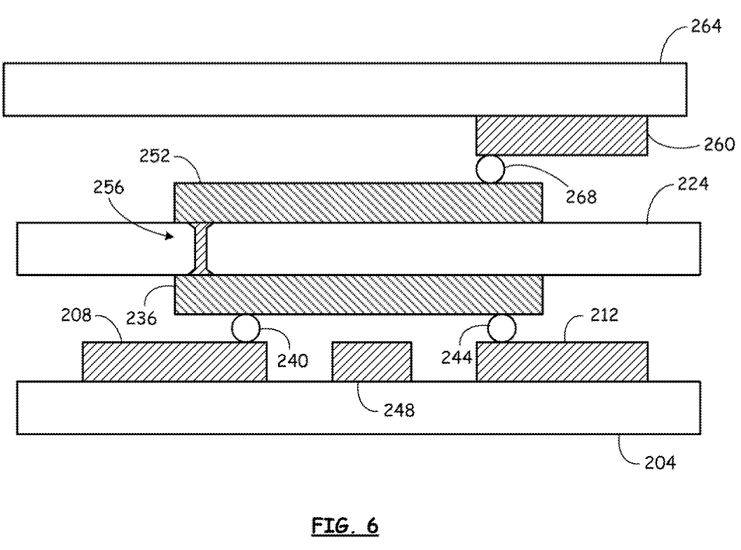

FIG. 6 is a functional diagram illustrating a structure and method according to one embodiment of the invention in which traces on at least three surfaces are operably coupled utilizing, in part, circuitry and methods of the embodiments of the present invention. As may be seen, the structure of FIG. 5 is included here in FIG. 6 with some additional structure. More specifically, the integrated circuit package of the embodiment of FIG. 5 further includes a fourth trace 252 formed on the second substrate 224 on a side opposite of the third trace 236. A via shown generally at 256 operably couples third trace 236 to fourth trace 252. Moreover, a fifth trace 260 is formed on a surface of a third substrate 264 to provide additional crossover coupling as discussed in relation to FIG. 5. A bump 268 operably couples fifth trace 260 to fourth trace 252.

In operation, a signal produced on trace 208, therefore, is present on traces 212, 236, 252 and 260 in the described embodiment. Such a signal may include, for example, a supply for circuitry of a plurality of devices of a multi-chip module for one embodiment as shown in FIG. 6. Via 256 is not required, however. Thus, the embodiment of FIG. 6 may also merely comprise a multi-chip module utilizing the structure and method of the embodiments of the present invention to merely provide crossover coupling as described in relation to FIG. 5. Via 256 is used in this embodiment to provide a signal to circuit paths on at least three surfaces of at least two adjacent substrates. In general, the embodiment of FIG. 6 represents a vertical integration to allow a signal to be distributed across two or more surfaces of two or more substrate devices of any type including boards, bare die, etc. Generally, stacked substrates are use to provide coupling between nodes that have circuitry or other nodes in between them. Any known application that includes vertically stacked substrates of any type may employ the concepts of the embodiments of the invention.

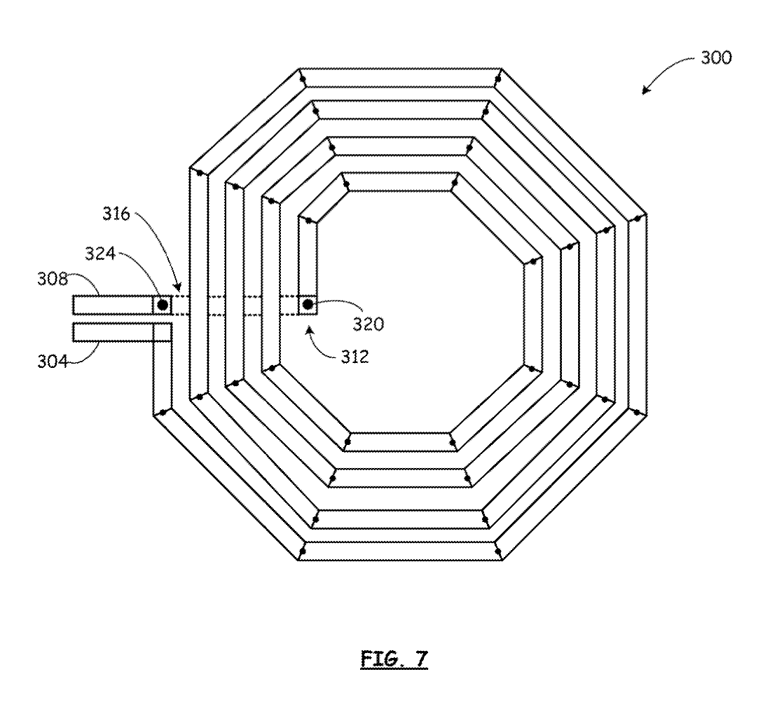

FIG. 7 is a functional schematic diagram of a coil utilizing the structure and method according to one embodiment of the invention. As may be seen, a coil generally shown at 300, includes a trace defining an input 304 and an output 308. In the prior art, a pair of vias would be used to route the end of the coil shown generally at 312 to the output 308 of the coil 300. Here, however, a trace shown generally in dashed lines at 316 and bumps 320 and 324 operably couple end 312 to output 308. As described in relation to FIGS. 5 and 6, trace 316 is formed on a surface of a different substrate and is pressed into connectivity with output 308 and coil end 312 by bumps 320 and 324. The different substrate may be a different die, printed circuit board or other structure.

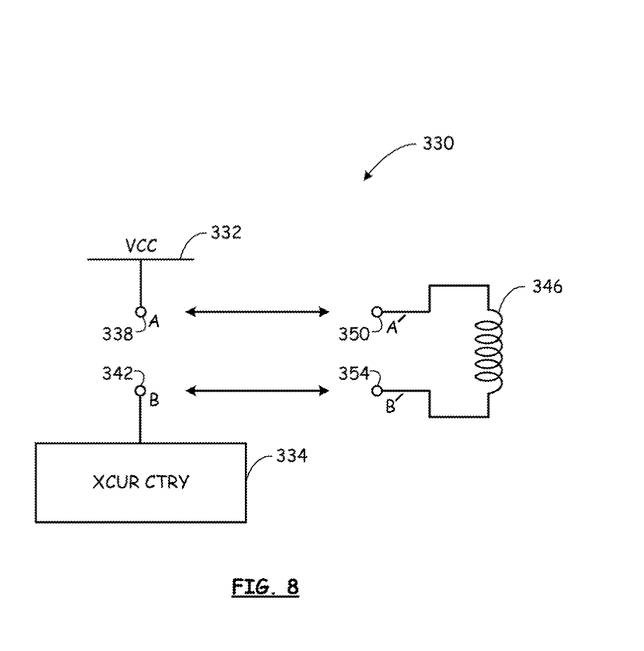

FIG. 8 is a functional diagram that illustrates yet another aspect of the embodiments of the invention. As may be seen, a circuit such as a transceiver may be formed on a first substrate while a coil is formed on a second substrate. More specifically, in the example of FIG. 8, a module 330 includes a supply 332 labeled as VCC and transceiver circuitry 334 that are each operably coupled to nodes 338 and 342, respectively. A coil 346 is operably coupled to nodes 350 and 354. Though not specifically shown here, nodes 338 and 350 are coupled by a first bump and nodes 342 and 354 are coupled by a second bump when a structure upon which coil 346 is formed is aligned and pressed against the first and second bumps.

As before, the structure upon which the transceiver circuitry 334 is formed and the structure upon which the coil 346 is formed may each be any one of a die, a printed circuit board or other substrate structure. Generally, the module 330 may include any circuit in place of transceiver circuitry 334 and supply 332 for which a coil 346 is required. Thus, the embodiment of FIG. 8 is advantageous is that it provides a method to couple a coil to bare die or other compact circuit for which space for a coil may be difficult to provide. Referring again to the example of FIG. 6, trace 260 may comprise a coil or antenna to which circuitry of substrates 204 and 224 may couple for communications and other purposes.

More generally, the above embodiments for an integrated circuit package include a first substrate device, first and second nodes of a circuit on an outer surface of the first substrate device, a second substrate device, and a trace on the second substrate device. First and second bumps operably couple the trace on the second substrate device to the first and second nodes on the first substrate device and are thus operable to provide crossover coupling. The trace on the second substrate crosses circuit paths of the circuit on the outer surface of the first substrate device to conduct signals processed on the first substrate device from the first node to the second node. The bumps are substantially smaller than a typical via used to create alternate signal paths with a substrate device to support crossover signal paths. The substrate devices may comprise anyone of a flip chip, a bare die, a printed circuit board or a package substrate.

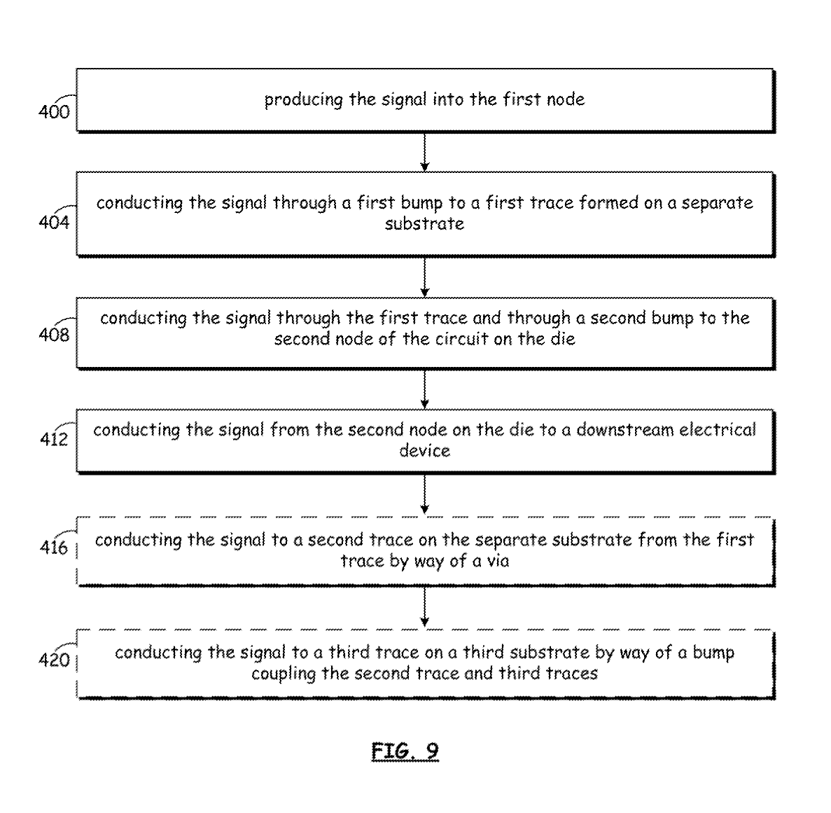

FIG. 9 is a flow chart illustrating a method according to one embodiment of the invention. Generally, the method of the embodiment of FIG. 9 is a method for conducting a signal from a first node of a circuit on a die to a second node of the circuit on the die or other substrate. The method generally includes producing the signal into the first node (step 400) and conducting the signal through a first bump to a first trace formed on a separate substrate (step 404). The method further includes conducting the signal through the first trace and through a second bump to the second node of the circuit on the die (step 408). The first trace through which the signal is conducted is one that crosses over another trace, node or object that physically blocks a connection from the first node to the second node. Finally, the method includes conducting the signal from the second node on the die to a downstream electrical device (step 412).

Thus, the above described method includes conducting the signal through the trace includes crossing at least one separate electrical node of the circuit without coupling to the at least one separate node of the circuit. In an alternate embodiment, the method further includes conducting the signal to a second trace on the separate substrate from the first trace by way of a via (step 416) and conducting the signal to a third trace on a third substrate by way of a bump coupling the second trace and third traces (step 420).

As one of ordinary skill in the art will appreciate, the term “substantially” or “approximately”, as may be used herein, provides an industry-accepted tolerance to its corresponding term and/or relativity between items. Such an industry-accepted tolerance ranges from less than one percent to twenty percent and corresponds to, but is not limited to, component values, integrated circuit process variations, temperature variations, rise and fall times, and/or thermal noise. Such relativity between items ranges from a difference of a few percent to magnitude differences. As one of ordinary skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled”.

While the invention is susceptible to various modifications and alternative forms, specific embodiments thereof have been shown by way of example in the drawings and detailed description. It should be understood, however, that the drawings and detailed description thereto are not intended to limit the invention to the particular form disclosed, but, on the contrary, the invention is to cover all modifications, equivalents and alternatives falling within the spirit and scope of the present invention as defined by the claims. As may be seen, the described embodiments may be modified in many different ways without departing from the scope or teachings of the invention.

1. An integrated circuit package, comprising:
first substrate device;
a first circuit path comprising first and second traces on an outer surface of the first substrate device operably defining first and second electrical connection points on the first substrate device;
second substrate device; and
a second circuit path comprising a third trace formed on the second substrate device operably defining third and fourth electrical connection points on the second substrate device; and
first and second bumps coupling the third and fourth connection points of the third trace on the second substrate device to the first and second connection points of the first and second traces on the first substrate device to form a hybrid passive structure to provide crossover coupling.

2. The integrated circuit package of claim 1 wherein the third trace crosses over a fourth trace to conduct signals processed on the first substrate device from the first trace to the second trace.

3. The integrated circuit package of claim 1 wherein the first and second bumps are both substantially smaller than a typical via used to create alternate signal paths with a substrate device to support crossover signal paths.

4. The integrated circuit package of claim 1 wherein the first substrate device comprises a flip chip and the second substrate device comprises one of a printed circuit board or a package substrate.

5. The integrated circuit package of claim 1 wherein the first substrate device comprises one of a printed circuit board or a package substrate and the second substrate device comprises a flip chip.

6. The integrated circuit package of claim 1 wherein the first substrate device comprises a first die of a multi-chip module and wherein the second substrate device comprises a second die of a multi-chip module.

7. The integrated circuit package of claim 1 further including a third trace formed on the second substrate device on a side opposite of the second trace.

8. The integrated circuit package of claim 7 wherein the third trace formed on the second substrate device on a side opposite of the second trace is coupled to the second trace by way of a via.

9. The integrated circuit package of claim 1 further including a fourth trace formed on a third substrate device operably coupled to the third trace by at least one bump.

10. An integrated circuit package, comprising:
first substrate device;
first and second nodes of a circuit on an outer surface of the first substrate device;
second substrate device;
a trace on the second substrate device; and
first and second bumps coupling the trace on the second substrate device to the first and second nodes on the first substrate device operable to provide crossover coupling.

11. The integrated circuit package of claim 10 wherein the trace crosses circuit paths of the circuit on the outer surface of the first substrate device to conduct signals processed on the first substrate device from the first node to the second node.

12. The integrated circuit package of claim 10 wherein the first and second bumps are both substantially smaller than a typical via used to create alternate signal paths with a substrate device to support crossover signal paths.

13. The integrated circuit package of claim 10 wherein the first substrate device comprises a flip chip and the second substrate device comprises one of a printed circuit board or a package substrate.

14. The integrated circuit package of claim 10 wherein the first substrate device comprises one of a printed circuit board or a package substrate and the second substrate device comprises a flip chip.

15. The integrated circuit package of claim 10 wherein the first substrate device comprises a first die of a multi-chip module and wherein the second substrate device comprises a second die of a multi-chip module.

16. The integrated circuit package of claim 10 further including a second trace formed on the second substrate device on a side opposite of the first trace.

17. The integrated circuit package of claim 16 wherein the second trace formed on the second substrate device on a side opposite of the first trace is coupled to the second trace by way of a via.

18. The integrated circuit package of claim 16 further including a third trace formed on a third substrate device operably coupled to the second trace by at least one bump.

19. The integrated circuit package of claim 10 wherein the first and second substrates comprise any one of a board to package substrate, a package substrate to silicon device, a board to package to silicon device, a board to package in a direct chip attach application or a wire bonded silicon device to package substrate.

20. A method for conducting a signal from a first node of a circuit on a die to a second node of the circuit on the die, comprising:
producing the signal into the first node;
conducting the signal through a first bump to a first trace formed on a separate substrate;
conducting the signal through a second bump from the first trace formed on the separate substrate to the second node on the die; and
conducting the signal from the second node on the die to a downstream electrical device.

21. The method of claim 20 further including conducting the signal through the trace includes crossing at least one separate electrical node of the circuit without coupling to the at least one separate node of the circuit.

22. The method of claim 20 further including conducting the signal to a second trace on the separate substrate from the first trace by way of a via.

23. The method of claim 22 further including conducting the signal to a third trace on a third substrate by way of a bump coupling the second trace and third traces.
